(19) United States
(12) Patent Application Publication
(10) Pub. No.: US 2016/0370554 A1
(43) Pub. Date: Dec. 22, 2016

(54) STEPPER AUTOMATIC FILTER REPLACEMENT DEVICE AND STEPPER

(71) Applicant: SHENZHEN CHINA STAR OPTOELECTRONICS TECHNOLOGY CO., LTD., Shenzhen, Guangdong (CN)

(72) Inventor: Xialiang YUAN, Shenzhen, Guangdong (CN)

(73) Assignee: Shenzhen China Star Optoelectronics Technology Co., Shenzhen, Guangdong (CN)

(21) Appl. No.: 14/901,058

(22) PCT Filed: Sep. 18, 2015
(86) PCT No.: PCT/CN2015/090024

§ 371 Date: Dec. 27, 2015

(30) Foreign Application Priority Data
Feb. 4, 2015 (CN) 201510059956.3

(51) Int. Cl. G02B 7/00; G03F 7/20; G02F 1/13

(52) U.S. Cl. CPC G02B 7/006; G02F 1/1303; G03F 7/70191

(57) ABSTRACT

The present invention provides a stepper automatic filter replacement device, employed to clamp at least one filer, wherein the stepper automatic filter replacement device comprises a support, a rotation shaft installed at the support, a driving element and at least one clamping jaw, and the at least one clamping jaw is employed to clamp the filter; an extending arm is installed at periphery of the rotation shaft corresponding to the at least one clamping jaw, and the at least one clamping jaw is installed on the extending arm, and the driving element drives the rotation shaft to drive the extending arm to rotate, and to drive the filter to rotate. The present invention further provides a stepper.

### CROSS REFERENCE

This application claims the priority of Chinese Patent Application No. 201510059956.3, entitled “Stepper automatic filter replacement device and stepper”, filed on Feb. 4, 2015, the disclosure of which is incorporated herein by reference in its entirety.

### FIELD OF THE INVENTION

The present invention relates to a stepper automatic filter replacement device and a stepper.

### BACKGROUND OF THE INVENTION

During the manufacture process of the TFT substrate and the CF substrate of the liquid crystal display device, many times of exposure treatments are required to form the necessary patterns. In prior art, the stepper is employed for exposure. In the exposure process, the filter is required to replace because of various factors according to light resistance property. In the replacement process, the light lamp of the stepper needs to be off first. After cooling, the filter is manually unloaded and replaced. Such operation wastes working time, and the times of turning off light is more, which shortens the usage lifetime of the light lamp.

### SUMMARY OF THE INVENTION

An objective of the present invention is to provide a stepper automatic filter replacement device and a stepper saving operation time.

The present invention provides a stepper automatic filter replacement device, employed to clamp at least one filer, wherein the stepper automatic filter replacement device comprises a support, a rotation shaft installed at the support, a driving element and at least one clamping jaw, and the at least one clamping jaw is employed to clamp the filter; an extending arm is installed at periphery of the rotation shaft corresponding to the at least one clamping jaw, and the at least one clamping jaw is installed on the extending arm, and the driving element drives the rotation shaft to drive the extending arm to rotate, and to drive the filter to rotate.

An amount of the clamping jaws is four, and four extending arms are correspondingly installed on the rotation shaft.

The driving element is a driving motor.

The four extending arms are located to appear as a cross.

The present invention further provides a stepper, comprising a micro lens array, a plurality of filters and a stepper automatic filter replacement device, wherein the stepper automatic filter replacement device comprises a support, a rotation shaft installed at the support, a driving element and at least one clamping jaw, and the at least one clamping jaw is employed to clamp the filter; an extending arm is installed at periphery of the rotation shaft corresponding to the at least one clamping jaw, and the at least one clamping jaw is installed on the extending arm, and the stepper automatic filter replacement device is installed at an emitting light direction of the micro lens array, and the filter on the clamping jaw is oppositely located to the micro lens array, and the driving element drives the rotation shaft to drive the extending arm to rotate, and to drive the filter to rotate to achieve replacement of the filter corresponding to the micro lens array.

The driving element is a driving motor.

The stepper comprises a control device, an illuminator, a light lamp installed at the illuminator and a reflector assembly, and the illuminator is employed for light focus and transmits the light through the reflector assembly, and the control device is employed to control the micro lens array, the stepper automatic filter replacement device, the illuminator and the reflector assembly to work.

The illuminator comprises a focusing surface, and the light lamp is installed on the focusing surface, and light of the light lamp is focused and transmitted through the focusing surface.

The reflector assembly comprises a first reflector, a second reflector and a third reflector, and the first reflector is opposite to the focusing surface, and the second reflector receives the light reflected by the first reflector and transmits the light to the third reflector, and the third reflector emits the light for exposure.

The stepper automatic filter replacement device and the micro lens array are located between the first reflector and the second reflector, and the filter of the stepper is located between the second reflector and the micro lens array.

When the stepper of the present invention requires the filter replacement during the working procedure, only the rotation shaft 162 is driven to drive the extending arm to rotate, and to drive the filter to rotate for aligning the required filter to the micro lens array to achieve the automatic replacement of the filter to save the operation time.

### BRIEF DESCRIPTION OF THE DRAWINGS

In order to more clearly illustrate the embodiments of the present invention or prior art, the following figures will be described in the embodiments are briefly introduced. It is obvious that the drawings are merely some embodiments of the present invention, those of ordinary skill in this field can obtain other figures according to these figures without paying the premise.

FIG. 1 is a diagram of a stepper according to the preferred embodiment of the present invention.

FIG. 2 is a diagram of a stepper automatic filter replacement device of the stepper according to the present invention shown in FIG. 1.

### DETAILED DESCRIPTION OF PREFERRED EMBODIMENTS

Embodiments of the present invention are described in detail with the technical matters, structural features, achieved objects, and effects with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained, should be considered within the scope of protection of the present invention.

The embodiment of the present invention provides a stepper and a stepper automatic filter replacement device. The stepper is employed for exposure of the patterns to a plurality of CF substrates or TFT substrates. The stepper automatic filter replacement device is employed for automatically replacing the filter to achieve the replacement of the filter in time to photoresists of various substrates. In this embodiment, the manufacture of the CF substrate is illustrated for principle explanation of the stepper.

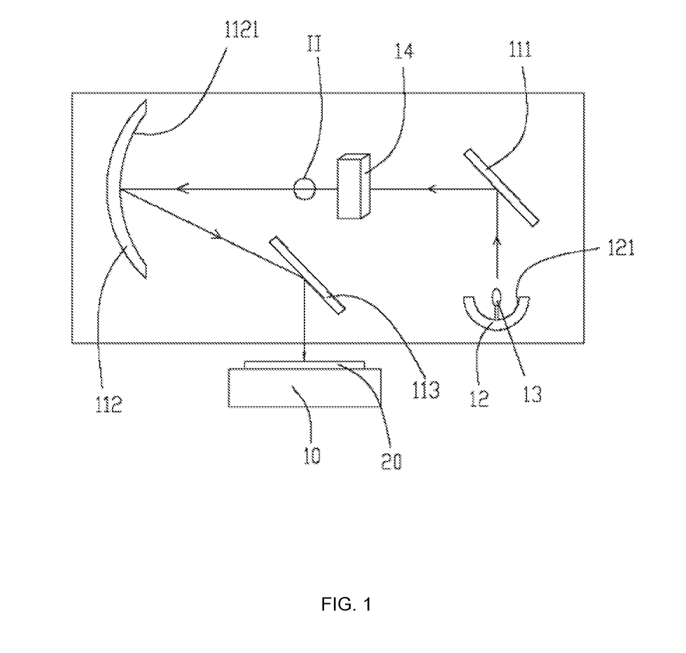

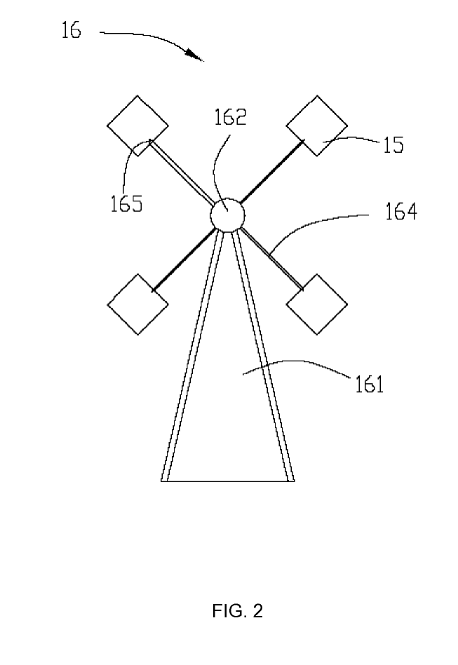

Please refer to FIG. 1 and FIG. 2. The part indicated with II shown in FIG. 1 refers to the stepper automatic filter replacement device 16 (in FIG. 2).The stepper comprises a platform 10 loading a CF substrate 20, a control device (not shown), an illuminator 12, a reflector assembly (not shown), a light lamp 13 installed at the illuminator 12, a micro lens array 14, a plurality of filters 15 and the stepper automatic filter replacement device 16. The illuminator 12 is employed for light focus and transmits the light through the reflector assembly. The control device is employed to control the micro lens array 14, the stepper automatic filter replacement device 16, the illuminator 12 and the reflector assembly to work.

In the embodiment, the stepper further comprises an accommodation control device (not shown), the illuminator 12, the reflector assembly (not shown), the light lamp 13 installed at the illuminator 12, the micro lens array 14, the plurality of filters 15 and a box (not shown) of the stepper automatic filter replacement device 16. The illuminator 12 is an arc structure, which comprises a circular arc focusing surface 121. The light lamp 13 is installed on the focusing surface 121. The light of the light lamp 13 is focused with the focusing surface 121 and transmitted out of the illuminator 12.

The reflector assembly comprises a first reflector 111, a second reflector 112 and a third reflector 113. The first reflector 111 is opposite to the focusing surface 121, and the second reflector 112 receives the light reflected by the first reflector 111 and transmits the light to the third reflector 113, and the third reflector 113 emits the light for exposure. In the embodiment, the second reflector 112 has an arc reflecting surface 1121. The first reflector 111 and the third reflector 113 are inclined and parallel with each other. The reflecting surface (not shown) of the third reflector 113 faces toward the surface of the CF substrate having light resistance. Meanwhile, a photomask jig (not shown) is further located between the light resistance of the CF substrate 20 and the third reflector 113.

In this embodiment, the micro lens array 14 is located between the first reflector 111 and the second reflector 112, and the filter is located between the second reflector 112 and the micro lens array 14.

In this embodiment, the stepper automatic filter replacement device comprises a support 161, a rotation shaft 162 installed at the support 161, a driving element (not shown) and at least one clamping jaw 165. The at least one clamping jaw 165 is employed to clamp the filter 15. An extending arm 164 is installed at periphery of the rotation shaft 162 corresponding to the at least one clamping jaw 165, and the at least one clamping jaw 165 is installed on the extending arm 164, and the driving element drives the rotation shaft 162 to drive the extending arm 164 to rotate, and to drive the filter 15 to rotate.

In this embodiment, an amount of the clamping jaws 165 is four, and four extending arms 164 are correspondingly installed on the rotation shaft 162. Moreover, the four extending arms are located at the periphery of the rotation shaft to appear as a cross. The driving element is a driving motor.

In other embodiments, there can be 1 clamping jaw 165 to be employed on the stepper and can be convenient for the replacement when it is required to clamp the filter or not to clamp the filter.

When the stepper of the present invention requires the replacement of the filter 15 during the working procedure, only the rotation shaft 162 is driven to drive the extending arm 164 to rotate, and to drive the filter 15 to rotate for aligning the required filter 15 to the micro lens array 14 to achieve the automatic replacement of the filter to save the operation time.

Above are embodiments of the present invention, which does not limit the scope of the present invention. Any modifications, equivalent replacements or improvements within the spirit and principles of the embodiment described above should be covered by the protected scope of the invention.

What is claimed is:

1. A stepper automatic filter replacement device, employed to clamp at least one filer, wherein the stepper automatic filter replacement device comprises a support, a rotation shaft installed at the support, a driving element and at least one clamping jaw, and the at least one clamping jaw is employed to clamp the filter; an extending arm is installed at periphery of the rotation shaft corresponding to the at least one clamping jaw, and the at least one clamping jaw is installed on the extending arm, and the driving element drives the rotation shaft to drive the extending arm to rotate, and to drive the filter to rotate.

2. The stepper automatic filter replacement device according to claim 1, wherein an amount of the clamping jaws is four, and four extending arms are correspondingly installed on the rotation shaft.

3. The stepper automatic filter replacement device according to claim 1, wherein the driving element is a driving motor.

4. The stepper automatic filter replacement device according to claim 3, wherein the four extending arms are located to appear as a cross.

5. A stepper, comprising a micro lens array, a plurality of filters and a stepper automatic filter replacement device, wherein the stepper automatic filter replacement device comprises a support, a rotation shaft installed at the support, a driving element and at least one clamping jaw, and the at least one clamping jaw is employed to clamp the filter; an extending arm is installed at periphery of the rotation shaft corresponding to the at least one clamping jaw, and the at least one clamping jaw is installed on the extending arm, and the stepper automatic filter replacement device is installed at an emitting light direction of the micro lens array, and the filter on the clamping jaw is oppositely located to the micro lens array, and the driving element drives the rotation shaft to drive the extending arm to rotate, and to drive the filter to rotate to achieve replacement of the filter corresponding to the micro lens array.

6. The stepper according to claim 5, wherein the driving element is a driving motor.

7. The stepper according to claim 6, wherein the stepper comprises a control device, an illuminator, a light lamp installed at the illuminator and a reflector assembly, and the illuminator is employed for light focus and transmits the light through the reflector assembly, and the control device is employed to control the micro lens array, the stepper automatic filter replacement device, the illuminator and the reflector assembly to work.

8. The stepper according to claim 7, wherein the illuminator comprises a focusing surface, and the light lamp is installed on the focusing surface, and light of the light lamp is focused and transmitted through the focusing surface.

9. The stepper according to claim 8, wherein the reflector assembly comprises a first reflector, a second reflector and a third reflector, and the first reflector is opposite to the focusing surface, and the second reflector receives the light reflected by the first reflector and transmits the light to the third reflector, and the third reflector emits the light for exposure.

10. The stepper according to claim 9, wherein the stepper automatic filter replacement device and the micro lens array are located between the first reflector and the second reflector, and the filter of the stepper is located between the second reflector and the micro lens array.
